(19) United States
(12) Patent Application Publication
(10) Pub. No.: US 2020/0013363 A1
(43) Pub. Date: Jan. 9, 2020

(54) THIN FILM TRANSISTOR ARRAY SUBSTRATE AND DISPLAY PANEL USING SAME

(71) Applicant: Century Technology (Shenzhen) Corporation Limited, SHENZHEN (CN)

(72) Inventors: YUAN XIONG, Shenzhen (CN); NING FANG, Shenzhen (CN); CHIH-CHUNG LIU, New Taipei (TW); MING-TSUNG WANG, New Taipei (TW)

(21) Appl. No.: 16/170,502

(22) Filed: Oct. 25, 2018

(30) Foreign Application Priority Data
Jul. 5, 2018 (CN) 201810731337.8

(51) Int. Cl. G09G 3/36; G02F 1/1368; G02F 1/1362; H01L 27/12; G02F 1/1343

(52) U.S. Cl. CPC G09G 3/3688; G02F 1/1368; G02F 1/136286; H01L 27/1222; G02F 2201/123; G09G 2310/0251; G09G 2320/0233; G09G 3/3677; G02F 2001/134345; G02F 1/134309

(57) ABSTRACT

A display device comprising thin film transistor array substrate includes scan lines, data lines, pixel units, and a source driver. Each pair of scan lines extends in a first direction and data lines extend in a second intersecting direction. Of the first and second sub-pixels in each pixel unit, the first sub-pixel connects to the first scan line, and the second sub-pixel connects to the second scan line. The first and second sub-pixels also straddle and connect to one data line. Source driver supplies the data lines with voltages and the voltage to the first sub-pixel is greater than the voltage to the second sub-pixel. This configuration avoids appearance of stripes on the display arising from charging rates of adjacent pixel columns not being the same. A display panel using the thin film transistor array substrate is also provided.

### FIELD

The subject matter herein generally relates to displays using thin film transistors.

### BACKGROUND

In conventional liquid crystal display technology, gate driving methods include an IC driving method and a GOP (Gate on panel) driving method, and the difference between the IC driving method and the GOP driving method is that pre-charging exists during the GOP driving method.

Dual gates in a thin film transistor array substrate can reduce a number of data lines, thus data signal driving chip can be omitted. In the case of 2-dot inversion or 1+2-dot inversion, when adjacent columns of pixels are charged at a same potential, there will be differences in the charging rates of the two columns of pixels. Thus, the display panel will include bright and dark stripes, and the display quality will be reduced.

Therefore, there is room for improvement in the art.

### BRIEF DESCRIPTION OF THE DRAWINGS

Implementations of the present disclosure will now be described, by way of example only, with reference to the attached figures.

FIG. 1 is a cross-sectional view of a display panel.

FIG. 2 is a circuit diagram of a thin film transistor array substrate of the display panel of FIG. 1.

FIG. 3A and FIG. 3B are diagrammatic views of driving time sequences applied to the thin film transistor array substrate of FIG. 2.

FIG. 4A and FIG. 4B are diagrammatic views of driving time sequences of the thin film transistor array substrate of FIG. 2 obtained experimentally.

FIG. 5 is a cross-sectional view of part of the thin film transistor array substrate of FIG. 2.

FIG. 6A and FIG. 6B are diagrammatic views of driving time sequences of the thin film transistor array substrate of FIG. 5 obtained experimentally.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one.” The term “circuit” is defined as an integrated circuit (IC) with a plurality of electric elements, such as capacitors, resistors, amplifiers, and the like.

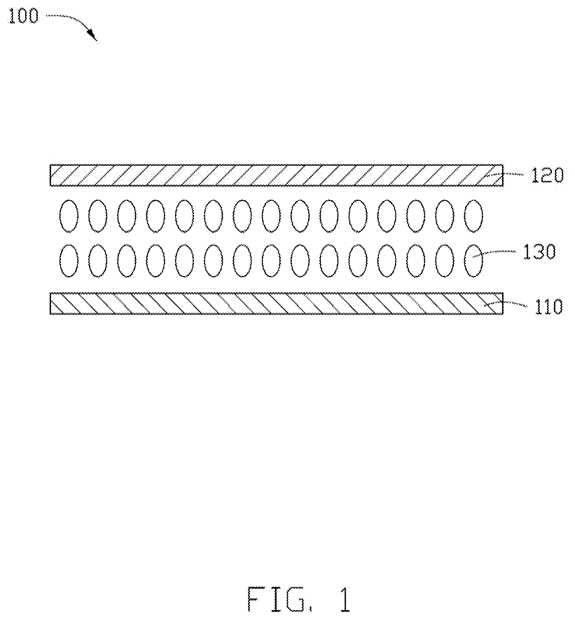

FIG. 1 illustrates a display panel 100 according to the application. The display panel 100 includes a color filter (CF) substrate 120, a liquid crystal layer 130, and a thin film transistor (TFT) substrate 110. The color filter substrate 120 and the thin film transistor array substrate 110 are on opposite sides of the the liquid crystal layer 130, which is located between the color filter substrate 120 and the thin film transistor array substrate 110.

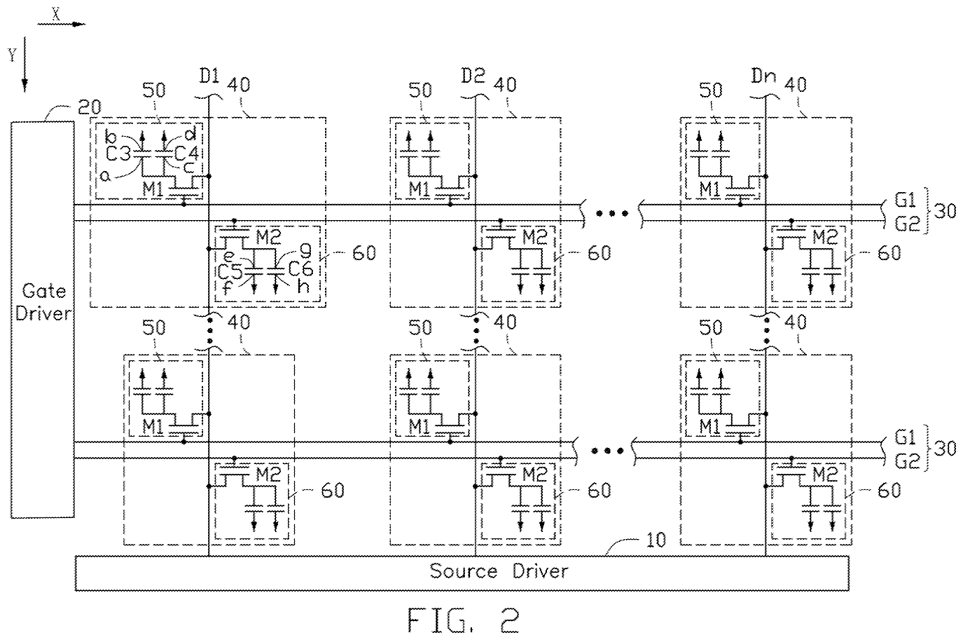

FIG. 2 shows the thin film transistor array substrate 110 including pairs of scan lines 30, data lines D1-Dn, and pixel units 40. Each pair of scan lines 30 includes a first scan line G1 and a second scan line G2 both extending in a first direction X. Each data line extends in a second direction Y intersecting with the first direction X. Each pixel unit 40 includes a first sub-pixel 50 and a second sub-pixel 60 on opposite sides of one pair of scan lines 30. The first sub-pixel 50 is electrically connected to the first scan line G1, and the second sub-pixel 60 is electrically connected to the second scan line G2. The first sub-pixel 50 and the second sub-pixel 60 in a pixel unit 40 are on opposite sides of, and electrically connected to, one of the data lines D1-Dn.

FIG. 2 shows the thin film transistor array substrate 110 including a gate driver 20 and a source driver 10. The first scan lines G1 and the second scan lines G2 are electrically connected to the gate driver 20. The data lines D1-Dn are electrically connected to the source driver 10. The gate driver 20 applies voltages for scanning to the first scan lines G1 and the second scan lines G2. The source driver 10 applies voltages as data to the first sub-pixels 50 and the second sub-pixels 60 through the data lines D1-Dn.

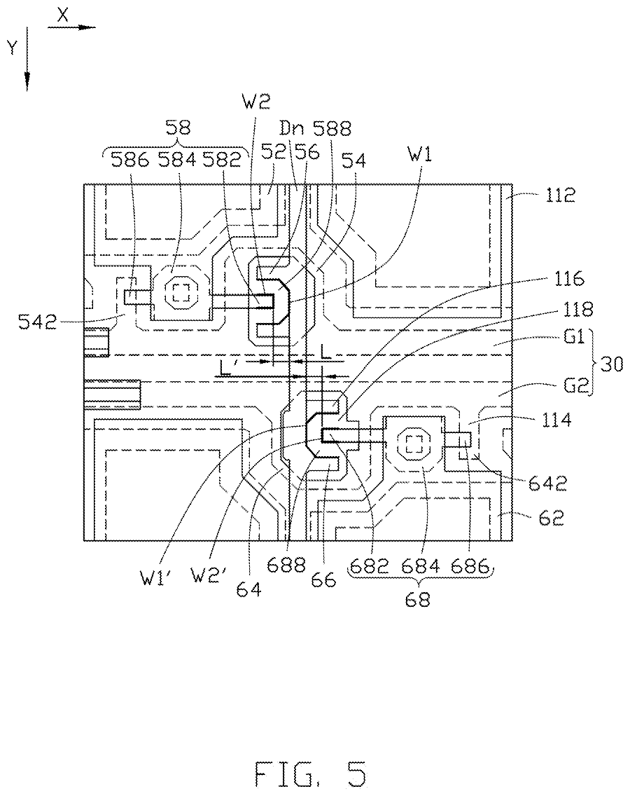

FIG. 2 shows the first sub-pixel 50 including a first sub-pixel electrode 52 (see FIG. 5), a first thin film transistor M1, a first liquid crystal capacitor C3, and a first storage capacitor C4. The first thin film transistor M1 includes a first gate electrode 54, a first source electrode 56, and a first drain electrode 58. The first gate electrode 54 is electrically connected to the first scan line G1. The first source electrode 56 is electrically connected to the data line Dn. The first liquid crystal capacitor C3 includes two ends (a and b). The first storage capacitor C4 includes two ends (c and d). The first drain electrode 58 is electrically connected to the end a of the first liquid crystal capacitor C3 and to the end c of the first storage capacitor C4.

In an embodiment, the source driver 10 applies a voltage to the first thin film transistor M1 by the data line Dn. The first scan line G1 controls the first thin film transistor M1 to receive the voltage, and thus controlling the charging and discharging of the first liquid crystal capacitor C3. The first storage capacitor C4 maintains a potential difference between two ends of the first liquid crystal capacitor C3 to prevent current leaking from the first liquid crystal capacitor C3.

FIG. 2 shows the second sub-pixel 60 includes a second sub-pixel electrode 62 (see FIG. 5), a second thin film transistor M2, a second liquid crystal capacitor C5, and a second storage capacitor C6. The second thin film transistor M2 includes a second gate electrode 64, a second source electrode 66, and a second drain electrode 68. The second gate electrode 64 is electrically connected to the second scan line G2. The second source electrode 66 is electrically connected to the data line Dn. The second liquid crystal capacitor C5 includes two ends (e and f). The second storage capacitor C6 includes two ends (g and h). The second drain electrode 68 is electrically connected to the end e of the second liquid crystal capacitor C5 and to the end g of the second storage capacitor C6.

In an embodiment, the source driver 10 applies a voltage to the second thin film transistor M2 by the data line Dn. The second scan line G2 controls the second thin film transistor M2 to receive the voltage and thus controlling the charging and discharging of the first liquid crystal capacitor C3. The second storage capacitor C6 maintains a potential difference between two ends of the second liquid crystal capacitor C5 to prevent current leaking from the second liquid crystal capacitor C5.

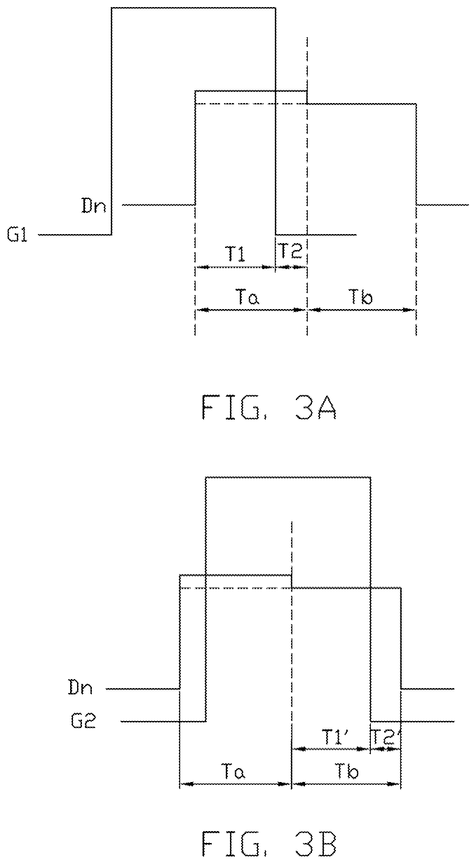

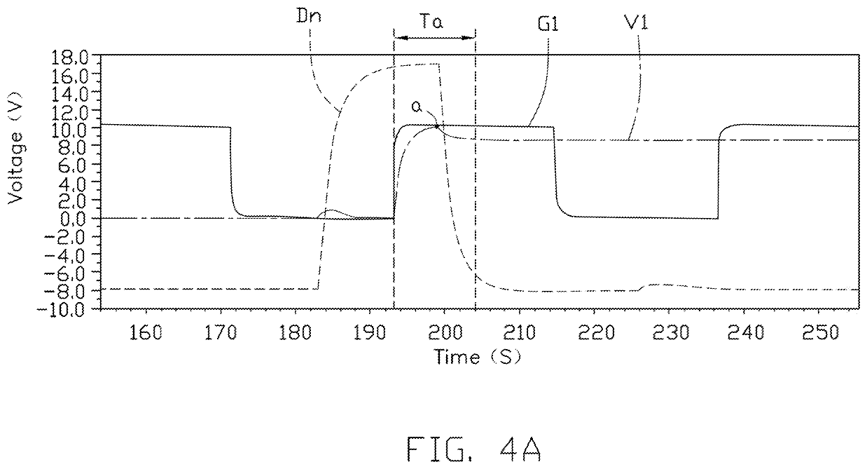

FIG. 3A and FIG. 3B show that in a pixel unit 40, one frame of image display time is divided into a first sub-driving period Ta and a second sub-driving period Tb. During the first sub-driving period Ta, the first sub-pixels 50 in the pixel units 40 are sequentially scanned, and the source driver 10 applies voltages to the first sub-pixel electrode 52 by the data lines D1-Dn. In the second sub-driving period Tb, the second sub-pixels 60 in the pixel units 40 are sequentially scanned, and the source driver 10 applies voltages to the second sub-pixel electrode 62 by the data lines D1-Dn.

FIG. 3A and FIG. 3B show that the first sub-driving period Ta includes a first charging period T1 and a first Output Enabling (OE) period T2. The second sub-driving period Tb includes a second charging period T1′ and a second OE period T2′. In an embodiment, During the first charging period T1, the source driver 10 applies voltages to the first sub-pixels 50 by the data lines D1-Dn. During the first OE period T2, the signals of the first scan line G1 and the OE signal are processed by a a logical AND gate, and the first scan line G1 is turned off in advance. During the second charging period T1′, the source driver 10 applies voltages to the second sub-pixel electrode 62 by the data lines D1-Dn. During the second OE period T2′, the signals of the second scan line G2 and the OE signal are ANDed, and the second scan line G2 is turned off in advance.

FIG. 3A shows during the first charging period T1 of the first sub-driving period Ta, the signal of the first scan line G1 is a logical high, and the signal of the data line Dn is a logical high. The first sub-pixel 50 electrically connected to the first scan line G1 receives the signal of the data line Dn as a data signal. During the first OE period T2 of the first sub-driving period Ta, the signal of the first scan line G1 is a logical low, the OE signal is a logical high.

FIG. 3B shows during the first charging period T1′ of the second sub-driving period Tb, the signal on the second scan line G2 is a logical high, and the signal of the data line Dn is a logical high. At this time, the second sub-pixels 60 which are electrically connected to the second scan line G2 receive the signal of the data line Dn as a data signal. During the first OE period T2′ of the second sub-driving period Tb, the signal on the second scan line G2 is a logical low, the OE signal is a logical high. The second scan line G2 is turned off in advance. In an embodiment, during the first charging period T1 of the first sub-driving period Ta, the voltage applied by the source driver 10 of the first sub-pixel electrode 52 is greater than the voltage applied by the source driver 10 of the second sub-pixel electrode 62 in the same pixel unit 40.

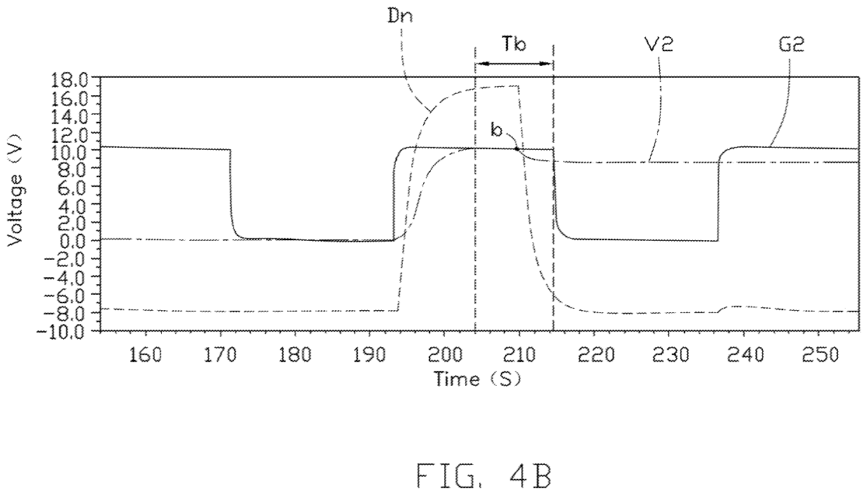

FIG. 4A shows during the first sub-driving period Ta, the signal of the first scan line G1 is a logical high, and the signal of the data line Dn is a logical high. The first sub-pixel 50 which is electrically connected to the first scan line G1 receives the signal of the data line Dn as a data signal. After the first sub-pixel electrode 52 is charged, the actual pixel voltage V1 on the first sub-pixel electrode 52 (as indicated by point a) is approximately 9.97913V.

FIG. 4B shows during the second sub-driving period Tb, the signal of the second scan line G2 is a logical high, and the signal of the data line Dn is a logical high. The second sub-pixel 60 electrically connected to the second scan line G2 receives the signal of the data line Dn as a data signal. FIG. 4A shows the voltage input by the data line Dn for the first sub-pixel electrode 52 is greater than the voltage input by the data line Dn for the second sub-pixel electrode 62 in the same pixel unit 40. After the second sub-pixel electrode 62 is charged, the actual pixel voltage V2 of the second sub-pixel electrode 62 (as indicated by point b) is approximately 10.00977V, which substantially coincides with the actual pixel voltage V1 of the first sub-pixel 50.

In an embodiment, in a case of 2-dot inversion, the voltage applied by the source driver 10 of the first sub-pixel electrode 52 is greater than the voltage applied by the source driver 10 of the second sub-pixel electrode 62, and the actual pixel voltage V1 of the first sub-pixel electrode 52 and the actual pixel voltage V2 of the second sub-pixel electrode 62 tend to be consistent with each other. Thus, the difference in pixel charging rates between adjacent columns of sub-pixels is reduced, and the striping phenomenon between light and dark is avoided, and the display quality is improved.

In a case of 1+2-dot inversion, the source driver 10 applies the voltage to the first sub-pixel electrode 52. This voltage is smaller than the voltage applied to the second sub-pixel electrode 62, and the actual pixel voltage V1 of the first sub-pixel electrode 52 and the actual pixel voltage V2 of the second sub-pixel electrode 62 tend to be consistent with each other. Thus, the difference in pixel charging rates between adjacent columns of sub-pixels is reduced, and the striping phenomenon between light and dark is avoided, and the display quality is improved.

FIG. 5 shows the thin film transistor array substrate 110 including a substrate 112, a first conductive layer 114 on the substrate 112, a second conductive layer 116 on a side of the first conductive layer 114 away from the substrate 112, and a semiconductor layer 118 between the first conductive layer 114 and the second conductive layer 116. In an embodiment, the first conductive layer 114 carries and defines the first scan lines G1, the second scan lines G2, the first gate electrodes 54, and the second gate electrodes 64. The second conductive layer 116 carries and defines the data lines D1-Dn, the first source electrodes 56, the first drain electrodes 58, the second source electrodes 66, and the second drain electrodes 68.

FIG. 5 shows the each of the first and second source electrodes 56 and 66 are substantially U-shaped and each defines an opening. The first drain electrode 58 includes a first inserting portion 582 and a first connecting portion 584. The first inserting portion 582 extends from the first connecting portion 584 into the opening of the first source electrode 56. The first connecting portion 584 is electrically connected to the first inserting portion 582 and electrically connected to the first sub-pixel electrode 52.

The second drain electrode 68 includes a second inserting portion 682 and a second connecting portion 684. The second inserting portion 682 extends from the second connecting portion 684 into the opening of the second source electrode 66. The second connecting portion 684 is electrically connected to the second inserting portion 682 and electrically connected to the second sub-pixel electrode 62.

In an embodiment, a portion of the semiconductor layer 118 between the first source electrode 56 and the first inserting portion 582 is defined as a first U-shaped channel 588. A portion of the semiconductor layer 118 between the second source electrode 66 and the second inserting portion 682 is defined as a second U-shaped channel 688.

In an embodiment, a first channel width W of the first U-shaped channel 588 is defined as (W1+W2)/2, wherein W1 is a first extension length of an outer sidewall of the first U-shaped channel 588. The outer sidewall of the first U-shaped channel 588 is the sidewall of the first U-shaped channel 588 away from the first drain electrode 58. W2 is a second extension length of an inner sidewall of the first U-shaped channel 588, the inner side wall of the first U-shaped channel 588 is the sidewall of the first U-shaped channel 588 close to the first drain electrode 58. A second channel width W′ of the second U-shaped channel 688 is defined as (W1′+W2′)/2, wherein W1′ is a third extension length, of an outer sidewall of the second U-shaped channel 688, and W2′ is a fourth extension length, of an inner sidewall of the second U-shaped channel 688. A first channel length L of the first U-shaped channel 588 is defined as the shortest extension length of the first U-shaped channel 588 along the first direction X. A second channel length L′ of the second U-shaped channel 688 is defined as the shortest extension length of the second U-shaped channel 688 along the first direction X.

FIG. 5 shows the second channel width W′ of the second U-shaped channel 688 being smaller than the first channel width W of the first U-shaped channel 588 (i.e., W′<W). The first channel length L of the first U-shaped channel 588 equals the second channel length L′ of the second U-shaped channel 688 (i.e., L′=L). Thus, in an embodiment, the width to length ratio of the channel of the second thin film transistor M2 is smaller than the width to length ratio of the channel of the first thin film transistor M1 (i.e., W′/L′<W/L). The magnitude of the charging current of a thin film transistor is proportional to the width-to-length ratio of the channel. In an embodiment, by creating differences in the channel widths of the first thin film transistor M1 and the second thin film transistor M2, the charging rate of the second sub-pixel 60 is low. Thus, after the chargings of the first sub-pixel 50 and the second sub-pixel 60 are completed, the actual pixel voltage V1 of the first sub-pixel electrode 52 and the actual pixel voltage V2 of the second sub-pixel electrode 62 tend to be consistent with each other. Thus, the differences in pixel charging rates between adjacent columns of sub-pixels is reduced, and the striping phenomenon between light and dark is avoided, and the display quality is improved.

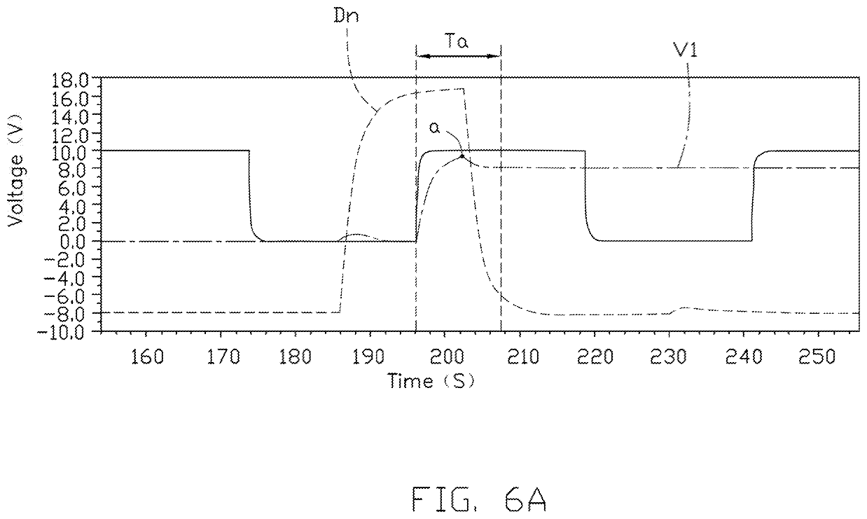

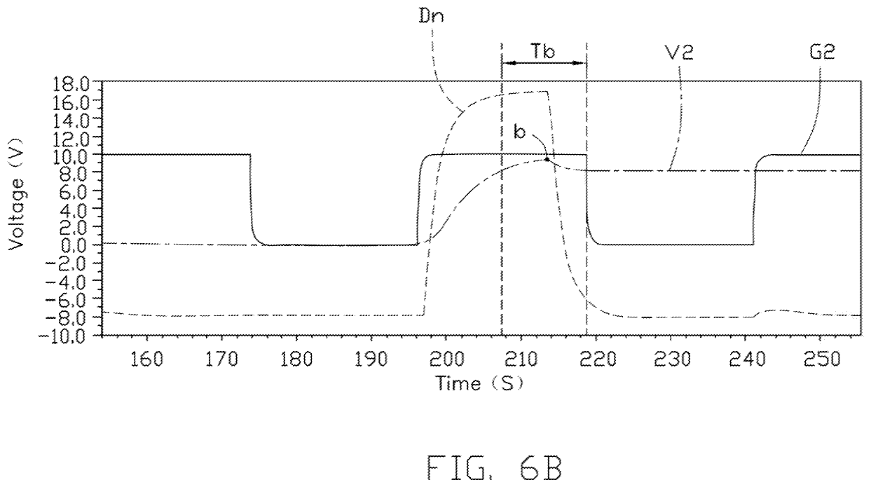

FIG. 6A shows during the first sub-driving period Ta, the signal of the first scan line G1 is a logical high, and the signal of the data line Dn is a logical high. The first sub-pixel 50 electrically connected to the first scan line G1 receives the signal of the data line Dn as a data signal. After the first sub-pixel 50 is charged, the actual pixel voltage V1 on the first sub-pixel electrode 52 (as indicated by point a) is approximately 9.34025V.

FIG. 6B shows during the second sub-driving period Tb, the signal of the second scan line G2 is a logical high, and the signal of the data line Dn is a logical high. The second sub-pixel 60 electrically connected to the second scan line G2 receives the signal of the data line Dn as a data signal. After the second sub-pixel 60 is charged, the actual pixel voltage V2 of the second sub-pixel electrode 62 (as indicated by point b) is approximately 9.36259V, which substantially coincides with the actual pixel voltage V1 of the first sub-pixel electrode 52.

In a case of 1+2-dot inversion, the first channel width W of the first U-shaped channel 588 is less than the second channel width W′ of the second U-shaped channel 688. (ie, W<W′). The first channel length L of the first U-shaped channel 588 equals the second channel length L′ of the second U-shaped channel 688 (i.e., L′=L). That is, the width to length ratio of the channel of the first thin film transistor M1 is less than the width to length ratio of the channel of the second thin film transistor M2 (i. e., W/L<W′/L′), and the charging rate of the first sub-pixel 50 is low. Thus, after the charging of the first sub-pixel 50 and the second sub-pixel 60 is completed, the actual pixel voltage V1 of the first sub-pixel electrode 52 and the actual pixel voltage V2 of the second sub-pixel electrode 62 tend to be consistent. Thus, the difference in pixel charging rates between adjacent columns of sub-pixels is reduced, and the striping phenomenon between light and dark is avoided, and the display quality is improved.

In an embodiment, the thin film transistor array substrate 110 includes compensating structures to decrease or increase an overlapping area of the first conductive layer and the second conductive layer. Thus, adverse consequences of misalignment between the first conductive layer and the second conductive layer can be avoided.

FIG. 5 shows the compensating structures include first drain compensating structure 586 and second drain compensating structure 686. The first drain compensating structure 586 is a branch extending from one first drain electrode 58. The first drain compensating structure 586 extends from the first drain electrode 58 to a side away from the first source electrode 56 to the first scan line G1 adjacent to the first drain electrode 58. The first drain compensating structure 586 partially overlaps with, but insulated from the first scan line G1 adjacent to the first drain electrode 58.

FIG. 5 shows the second drain compensating structure 686 is a branch extending from one second drain electrode 68. The second drain compensating structure 686 extends from one second drain electrode 68 to a side away from the second source electrode 66 to the second scan line G2 adjacent the second drain electrode 68. The second drain compensating structure 686 partially overlaps with, but insulated from the second scan line G2 adjacent to the second drain electrode 68.

The first drain compensating structure 586 is a branch extending from a side of one first connecting portion 584 away from the first inserting portion 582. The second drain compensating structure 686 is a branch extending from a side of one second drain connecting portion 684 away from the second inserting portion 682.

FIG. 5 shows the first drain electrode 58 overlaps with, but insulated from the first gate electrode 54. The first drain electrode 58 and the first gate electrode 54 cooperate to define a first gate-drain capacitance. The second drain electrode 68 overlaps with, but insulated from the second gate electrode 64. The second drain electrode 68 and the second gate electrode 64 cooperate to define a second gate-drain capacitance. In an embodiment, the first gate-drain capacitance equals the second gate-drain capacitance.

FIG. 5 shows the compensating structures further includes first gate compensating structure 542 and second gate compensating structure 642. The first gate compensating structure 542 is a protrusion extending from the first scan line G1 away from the second scan line G2 in one pair of scan lines 30. The first drain compensating structure 586 partially overlaps with, but insulated from one first gate compensating structure 542. The second gate compensating structure 642 is a protrusion extending from the second scan line G2 away from the first scan line G1 in one pair of scan lines 30. The second drain compensating structure 686 partially overlaps with, but insulated from one second gate compensating structure 642.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A thin film transistor array substrate, comprising:
a substrate;
a first conductive layer on the substrate, the first conductive layer defining a plurality of pairs of scan lines, each pair of scan lines comprising a first scan line and a second scan line wherein the first scan line and the second scan line extending in a first direction;
a second conductive layer on a side of the first conductive layer away from the substrate, the second conductive layer defining a plurality of data lines extending in a second direction intersecting with the first direction;
a plurality of pixel units, each pixel unit comprising a first sub-pixel and a second sub-pixel located on opposite sides of one of the plurality of pairs of scan lines, the first sub-pixel comprising a first sub-pixel electrode, the second sub-pixel comprising a second sub-pixel electrode, the first sub-pixel electrode and the second sub-pixel electrode located on opposite sides of one of the plurality of data lines; and
a source driver electrically connected to the plurality of data lines and applying data voltage signals to the plurality of data lines;
wherein the source driver applies a data voltage signal to the first sub-pixel electrode that is greater than a data voltage signal applied to the second sub-pixel electrode by the source driver.

2. The thin film transistor array substrate of claim 1, wherein the first sub-pixel further comprises a first thin film transistor; the first thin film transistor comprises a first gate electrode, a first source electrode, and a first drain electrode;
the first gate electrode is electrically connected to the first scan line; the first source electrode is electrically connected to one of the plurality of data lines; the first drain electrode is electrically connected to the first sub-pixel electrode;
the second sub-pixel further comprises a second thin film transistor; the second thin film transistor comprises a second gate electrode, a second source electrode, and a second drain electrode; and
the second gate electrode is electrically connected to the second scan line; the second source electrode is electrically connected to one of the plurality of data lines; and the second drain electrode is electrically connected to the second sub-pixel electrode.

3. The thin film transistor array substrate of claim 2, wherein each of the first source electrode and the second source electrode is substantially U-shaped and defines an opening;
the first drain electrode comprises a first connecting portion electrically connected to the first sub-pixel electrode and a first inserting portion extending from the first connecting portion into the opening of the first source electrode; and
the second drain electrode comprises a second connecting portion electrically connected to the second sub-pixel electrode and a second inserting portion extending from the second connecting portion into the opening of the second source electrode.

4. The thin film transistor array substrate of claim 3, wherein further comprises a semiconductor layer between the first conductive layer and the second conductive layer;
a portion of the semiconductor layer between the first source electrode and the first inserting portion is defined as a first U-shaped channel; and
a portion of the semiconductor layer between the second source electrode and the second inserting portion is defined as a second U-shaped channel; wherein
a first channel width of the first U-shaped channel is defined to be half of a sum of a first extension length of an outer sidewall of the first U-shaped channel and a second extension length of an inner sidewall of the first U-shaped channel;
a second channel width of the second U-shaped channel is defined to be half of a sum of a third extension length of an outer sidewall of the second U-shaped channel and a fourth extension length of an inner sidewall of the second U-shaped channel; and
the first channel width of the first U-shaped channel is greater than the second channel width of the second U-shaped channel.

5. The thin film transistor array substrate of claim 4, wherein the first conductive layer defines the first gate electrode and the second gate electrode; the second conductive layer defines the first source electrode, the first drain electrode, the second source electrode, and the second drain electrode.

6. The thin film transistor array substrate of claim 5, wherein the first drain electrode and the first gate electrode cooperate to define a first gate-drain capacitance, the second drain electrode and the second gate electrode cooperate to define a second gate-drain capacitance, and the first gate-drain capacitance equals the second gate-drain capacitance.

7. The thin film transistor array substrate of claim 6, wherein further comprises a plurality of compensating structures, the compensating structures are to decrease or increase an overlapping area between the first conductive layer and the second conductive layer in response to an amount of misalignment between the first conductive layer and the second conductive layer.

8. The thin film transistor array substrate of claim 7, wherein the plurality of compensating structures comprise a first drain compensating structure and a second drain compensating structure;
the first drain compensating structure is a branch extending from one first drain electrode to a side away from the first source electrode to the first scan line adjacent to the first drain electrode; the first drain compensating structure partially overlaps with, but insulated from the first scan line adjacent to the first drain electrode; and
the second drain compensating structure is a branch extending from one second drain electrode to a side away from the second source electrode to the second scan line adjacent to the second drain electrode; and the second drain compensating structure partially overlaps with, but insulated from the second scan line adjacent to the second drain electrode.

9. The thin film transistor array substrate of claim 8, wherein the first drain compensating structure is a branch extending from a side of one first connecting portion away from the first inserting portion, and the second drain compensating structures is a branch extending from a side of one second connecting portion away from the second inserting portion.

10. The thin film transistor array substrate of claim 8, wherein the plurality of compensating structures further comprise a first gate compensating structure and a second gate compensating structure;
the first gate compensating structures is a protrusion extending from the first scan line away from the second scan line in one pair of the plurality of pairs of scan lines, and the first gate compensating structure partially overlaps with, but insulated from one first drain compensating structure; and
the second gate compensating structure is a protrusion extending from the second scan line away from the first scan line in one pair of the plurality of pairs of scan lines, and the second gate compensating structure partially overlaps with, but insulated from one second drain compensating structure.

11. A display panel, comprising a color filter substrate, a thin film transistor array substrate, and a liquid crystal layer between the color filter substrate and the thin film transistor array substrate, the thin film transistor array substrate comprising:
a substrate;
a first conductive layer on the substrate, the first conductive layer defining a plurality of pairs of scan lines, each pair of scan lines comprising a first scan line and a second scan line wherein the first scan line and the second scan line extending in a first direction;
a second conductive layer on a side of the first conductive layer away from the substrate, the second conductive layer defining a plurality of data lines extending in a second direction intersecting with the first direction;
a plurality of pixel units, each pixel unit comprising a first sub-pixel and a second sub-pixel located on opposite sides of one of the plurality of pairs of scan lines, the first sub-pixel comprising a first sub-pixel electrode, the second sub-pixel comprising a second sub-pixel electrode, the first sub-pixel electrode and the second sub-pixel electrode located on opposite sides of one of the plurality of data lines; and
a source driver electrically connected to the plurality of data lines and applying data voltage signals to the plurality of data lines;
wherein the source driver applies a data voltage signal to the first sub-pixel electrode that is greater than a data voltage signal applied to the second sub-pixel electrode by the source driver.

12. The display panel of claim 11, wherein the first sub-pixel further comprises a first thin film transistor; the first thin film transistor comprises a first gate electrode, a first source electrode, and a first drain electrode;
the first gate electrode is electrically connected to the first scan line; the first source electrode is electrically connected to one of the plurality of data lines; the first drain electrode is electrically connected to the first sub-pixel electrode;
the second sub-pixel further comprises a second thin film transistor; the second thin film transistor comprises a second gate electrode, a second source electrode, and a second drain electrode; and
the second gate electrode is electrically connected to the second scan line; the second source electrode is electrically connected to one of the plurality of data lines; and the second drain electrode is electrically connected to the second sub-pixel electrode.

13. The display panel of claim 12, wherein each of the first source electrode and the second source electrode is substantially U-shaped and defines an opening;
the first drain electrode comprises a first connecting portion electrically connected to the first sub-pixel electrode and a first inserting portion extending from the first connecting portion into the opening of the first source electrode; and
the second drain electrode comprises a second connecting portion electrically connected to the second sub-pixel electrode and a second inserting portion extending from the second connecting portion into the opening of the second source electrode.

14. The display panel of claim 13, wherein further comprises a semiconductor layer between the first conductive layer and the second conductive layer;
a portion of the semiconductor layer between the first source electrode and the first inserting portion is defined as a first U-shaped channel; and
a portion of the semiconductor layer between the second source electrode and the second inserting portion is defined as a second U-shaped channel; wherein
a first channel width of the first U-shaped channel is defined to be half of a sum of a first extension length of an outer sidewall of the first U-shaped channel and a second extension length of an inner sidewall of the first U-shaped channel;
a second channel width of the second U-shaped channel is defined to be half of a sum of a third extension length of an outer sidewall of the second U-shaped channel and a fourth extension length of an inner sidewall of the second U-shaped channel; and
the first channel width of the first U-shaped channel is greater than the second channel width of the second U-shaped channel.

15. The display panel of claim 14, wherein the first conductive layer defines the first gate electrode and the second gate electrode; the second conductive layer defines the first source electrode, the first drain electrode, the second source electrode, and the second drain electrode.

16. The display panel of claim 15, wherein the first drain electrode and the first gate electrode cooperate to define a first gate-drain capacitance, the second drain electrode and the second gate electrode cooperate to define a second gate-drain capacitance, and the first gate-drain capacitance equals the second gate-drain capacitance.

17. The display panel of claim 16, wherein further comprises a plurality of compensating structures, the compensating structures are to decrease or increase an overlapping area between the first conductive layer and the second conductive layer in response to an amount of misalignment between the first conductive layer and the second conductive layer.

18. The display panel of claim 17, wherein the plurality of compensating structures comprise a first drain compensating structure and a second drain compensating structure;
the first drain compensating structure is a branch extending from one first drain electrode to a side away from the first source electrode to the first scan line adjacent to the first drain electrode; the first drain compensating structure partially overlaps with, but insulated from the first scan line adjacent to the first drain electrode; and
the second drain compensating structure is a branch extending from one second drain electrode to a side away from the second source electrode to the second scan line adjacent to the second drain electrode; and the second drain compensating structure partially overlaps with, but insulated from the second scan line adjacent to the second drain electrode.

19. The display panel of claim 18, wherein the first drain compensating structure is a branch extending from a side of one first connecting portion away from the first inserting portion, and the second drain compensating structures is a branch extending from a side of one second connecting portion away from the second inserting portion.

20. The display panel of claim 18, wherein the plurality of compensating structures further comprise a first gate compensating structure and a second gate compensating structure;
the first gate compensating structures is a protrusion extending from the first scan line away from the second scan line in one pair of the plurality of pairs of scan lines, and the first gate compensating structure partially overlaps with, but insulated from one first drain compensating structure; and
the second gate compensating structure is a protrusion extending from the second scan line away from the first scan line in one pair of the plurality of pairs of scan lines, and the second gate compensating structure partially overlaps with, but insulated from one second drain compensating structure.
